(19) United States
(12) Patent Application Publication
(10) Pub. No.: US 2024/0079377 A1
(43) Pub. Date: Mar. 7, 2024

(54) STACKED INTEGRATED CIRCUIT CONFIGURED TO DISTINGUISH CHIPS WITHIN STACKED CHIPS

(71) Applicant: SK hynix Inc., Icheon-si (KR)

(72) Inventor: Dong Uk LEE, Icheon-si (KR)

(73) Assignee: SK hynix Inc., Icheon-si (KR)

(21) Appl. No.: 18/096,427

(22) Filed: Jan. 12, 2023

(30) Foreign Application Priority Data
Sep. 5, 2022 (KR) 10-2022-0112435

(51) Int. Cl. H01L 25/065; H01L 23/00

(52) U.S. Cl. CPC H01L 25/0657; H01L 24/08; H01L 2224/08145; H01L 2225/06562

(57) ABSTRACT

A stacked integrated circuit includes an upper chip that is rotated around a rotation axis and stacked on a lower chip in the form of a mirror symmetric structure. The lower chip and the upper chip are stacked in the form of a front and front connection structure. The upper chip is configured to generate a first internal distinguishment signal based on a distinguishment signal. The upper chip is configured to generate a first input/output control signal for the input/output of a power signal based on the first internal distinguishment signal and a chip selection signal. The lower chip is configured to generate a second internal distinguishment signal based on a reset signal. The lower chip is configured to generate a second input/output control signal for the input/output of the power signal based on the second internal distinguishment signal and the chip selection signal.

### CROSS-REFERENCE TO RELATED APPLICATION

The present application claims priority under 35 U.S.C. § 119(a) to Korean application number 10-2022-0112435, filed in the Korean Intellectual Property Office on Sep. 5, 2022, the entire disclosure of which is incorporated herein by reference.

### BACKGROUND

### 1. Technical Field

The present disclosure generally relates to a stacked integrated circuit, and more particularly, to a stacked integrated circuit configured to distinguish chips within stacked chips.

### 2. Related Art

Recently, in order to improve the degree of integration, a stacked integrated circuit in which a plurality of chips that are bonded together are stacked and formed is used. The plurality of chips that are included in the stacked integrated circuit may mutually transmit data in addition to power and control signals for controlling various operations through through vias. In order to perform a test on each of the stacked chips that are included in the stacked integrated circuit, there is a need for a method capable of distinguishing between chips with in the stacked chips.

### SUMMARY

In an embodiment, a stacked integrated circuit may include an upper chip that is rotated around a rotation axis and stacked on a lower chip in the form of a mirror symmetric structure. The lower chip and the upper chip may be stacked in the form of a front and front connection structure. The upper chip is configured to generate a first internal distinguishment signal based on a distinguishment signal. The upper chip is configured to generate a first input/output control signal for the input/output of a power signal based on the first internal distinguishment signal and a chip selection signal. The lower chip is configured to generate a second internal distinguishment signal based on a reset signal. The lower chip is configured to generate a second input/output control signal for the input/output of the power signal based on the second internal distinguishment signal and the chip selection signal.

In an embodiment, a stacked integrated circuit may include an upper chip that is rotated around a rotation axis and stacked on a lower chip in the form of a mirror symmetric structure. The lower chip and the upper chip may be stacked in the form of a front and front connection structure. Each of the lower chip and the upper chip may be configured to control the input of a first power signal and a second power signal based on an internal distinguishment signal and an input/output control signal.

In an embodiment, a stacked integrated circuit may include an upper chip that is rotated around a rotation axis and stacked on a lower chip in the form of a mirror symmetric structure. The lower chip and the upper chip may be stacked in the form of a front and front connection structure. Each of the lower chip and the upper chip may be configured to control the output of a first power signal and a second power signal based on an internal distinguishment signal and an input/output control signal.

### BRIEF DESCRIPTION OF THE DRAWINGS

FIG. 1 is a plan view illustrating a construction of a chip according to an example of the present disclosure.

FIG. 2 is a side view of a stacked integrated circuit according to an example of the present disclosure.

FIG. 3 is a diagram illustrating a connection relation between pads that are included in the stacked integrated circuit illustrated in FIG. 2.

FIG. 4 is a side view of a stacked integrated circuit according to another example of the present disclosure.

FIG. 5 is a circuit diagram of a first internal distinguishment generation circuit according to an example of the present disclosure.

FIG. 6 is a circuit diagram of a first input/output control signal generation circuit according to an example of the present disclosure.

FIG. 7 is a circuit diagram of a second internal distinguishment generation circuit according to an example of the present disclosure.

FIG. 8 is a circuit diagram of a second input/output control signal generation circuit according to an example of the present disclosure.

FIGS. 9, 10, and 11 are side views for describing an operation of the stacked integrated circuit according to an example of the present disclosure.

FIG. 12 is a side view of a stacked integrated circuit according to still another example of the present disclosure.

FIG. 13 is a circuit diagram according to an example of a first power signal input circuit according to an example of the present disclosure.

FIG. 14 is a circuit diagram according to an example of a second power signal input circuit according to an example of the present disclosure.

FIG. 15 is a side view of a stacked integrated circuit according to still another example of the present disclosure.

FIG. 16 is a circuit diagram according to an example of a first power signal output circuit that is included in the stacked integrated circuit illustrated in FIG. 15.

FIG. 17 is a circuit diagram according to an example of a second power signal output circuit that is included in the stacked integrated circuit illustrated in FIG. 15.

FIG. 18 is a block diagram of a construction illustrating an electronic system according to an example of the present disclosure.

FIG. 19 is a block diagram of a construction illustrating an electronic system according to another example of the present disclosure.

### DETAILED DESCRIPTION

In the descriptions of the following embodiments, the term “preset” indicates that the numerical value of a parameter is previously decided, when the parameter is used in a process or algorithm. According to an embodiment, the numerical value of the parameter may be set when the process or algorithm is started or while the process or algorithm is performed.

Terms such as “first” and “second,” which are used to distinguish among various components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

A “logic bit set” may mean a combination of logic levels of bits included in a signal. When a logic level of each of the bits included in the signal is changed, a logic bit set of the signal may be differently set. For example, if two bits are included in a signal, a logic bit set of the signal may be set as a first logic bit set when logic levels of the two bits included in the signal are a “logic low level” and a “logic low level”, and may be set as a second logic bit set when logic levels of the two bits included in the signal are a “logic low level”, and a “logic high level.”

Hereafter, the teachings of the present disclosure will be described in more detail through embodiments. The embodiments are only used to exemplify the teachings of the present disclosure, and the scope of the present disclosure is not limited by the embodiments.

Various embodiments relate to a stacked integrated circuit capable of distinguishing between chips within stacked chips.

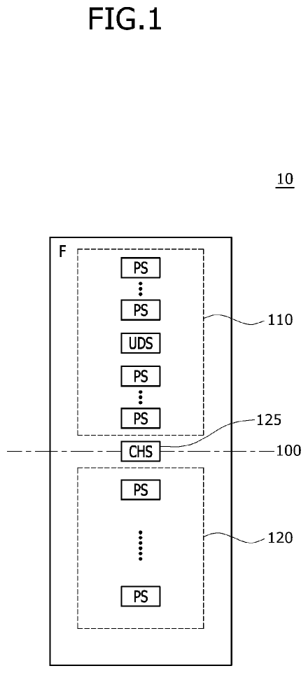

FIG. 1 is a plan view illustrating a construction of a chip according to an example of the present disclosure. As illustrated in FIG. 1, the chip 10 may include an upper area 110 that is disposed on the upper side of a rotation axis 100 and a lower area 120 that is disposed on the lower side of the rotation axis 100. The upper area 110 may include multiple pads to which separate power signals PS are input, respectively, and a pad to which a distinguishment signal UDS is input. The power signal PS may include various power sources that are used in the chip 10, for example, a power supply voltage, a ground voltage, and a high voltage, and may include a control signal and data for controlling various operations, etc. The lower area 120 may include multiple pads to which separate power signals PS are input. A pad 125 to which a chip selection signal CHS is input may be disposed at the rotation axis 100. In an embodiment, a pad 125 to which a chip selection signal CHS is input may be disposed between the upper area 110 and the lower area 120 and at the rotation axis 100. In different embodiments, the pad 125 to which the chip selection signal CHS is input may be implemented to be disposed in the upper area 110 or the lower area 120.

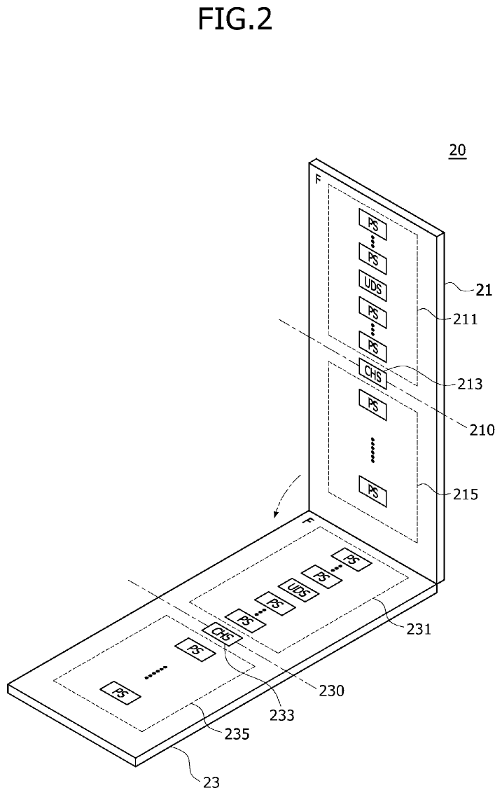

FIG. 2 is a side view of a stacked integrated circuit 20 according to an example of the present disclosure. As illustrated in FIG. 2, the stacked integrated circuit 20 may include an upper chip 21 and a lower chip 23.

The upper chip 21 may include a first upper area 211 that is disposed on the upper side of a first rotation axis 210 and a first lower area 215 that is disposed on the lower side of the first rotation axis 210. The first upper area 211 may include multiple pads to which separate power signals PS are input, respectively, and a pad to which a distinguishment signal UDS is input. The first lower area 215 may include multiple pads to which separate power signals PS are input, respectively. A pad 213 to which a chip selection signal CHS is input may be disposed at the first rotation axis 210. In an embodiment, a pad 123 to which a chip selection signal CHS is input may be disposed between the first upper area 211 and the first lower area 215 and at the rotation axis 210. In different embodiments, the pad 213 to which the chip selection signal CHS is input may be implemented to be disposed in the first upper area 211 or the first lower area 215.

The lower chip 23 may include a second upper area 231 that is disposed on the upper side of a second rotation axis 230 and a second lower area 235 that is disposed on the lower side of the second rotation axis 230. The second upper area 231 may include multiple pads to which separate power signals PS are input, respectively, and a pad to which a distinguishment signal UDS is input. The second lower area 235 may include multiple pads to which separate power signals PS are input, respectively. A pad 233 to which a chip selection signal CHS is input may be disposed at the second rotation axis 230. In an embodiment, a pad 233 to which a chip selection signal CHS is input may be disposed between the second upper area 231 and the second lower area 235 and at the rotation axis 230. In different embodiments, the pad 233 to which the chip selection signal CHS is input may be implemented to be disposed in the second upper area 231 or the second lower area 235.

The upper chip 21 may be rotated around the first rotation axis 210, may be stacked on the lower chip 23 in the form of a mirror symmetric structure, and may form the stacked integrated circuit 20. When the upper chip 21 and the lower chip 23 that are included in the stacked integrated circuit 20 are stacked in the form of the mirror symmetric structure, the upper chip 21 and the lower chip 23 may be formed in the form of a front and front connection structure in which a front F of the upper chip 21 and a front F of the lower chip 23 are connected. More specifically, the first lower area 215 of the upper chip 21 may be stacked on the second upper area 231 of the lower chip 23, and the first upper area 211 of the upper chip 21 may be stacked on the second lower area 235 of the lower chip 23 when, for example, the upper chip 21 is stacked onto the lower chip 23 in the direction of the arrow, indicated, and shown in for example FIG. 2. The pad 213 to which the chip selection signal CHS is input in the upper chip 21 may be stacked on the pad 233 to which the chip selection signal CHS is input in the lower chip 23 when, for example, the upper chip 21 is stacked onto the lower chip 23 in the direction of the arrow, indicated, and shown in for example FIG. 2.

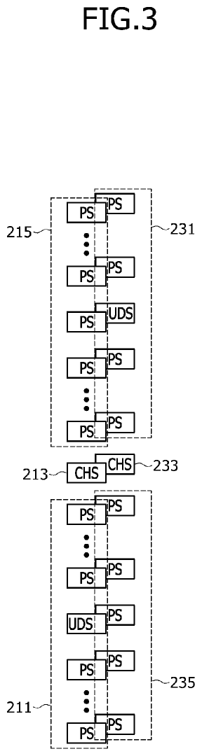

FIG. 3 is a diagram illustrating a connection relation between pads that are included in the stacked integrated circuit 20. As illustrated in FIG. 3, the pads to which the separate power signals PS are input, respectively, in the first lower area 215 of the upper chip 21 may be connected to the pads to which the separate power signals PS are input, respectively, and the pad to which the distinguishment signal UDS is input, respectively, in the second upper area 231 of the lower chip 23. Furthermore, as illustrated in FIG. 3, the pad 233 to which the chip selection signal CHS is input in the lower chip 23 may be connected to the pad 213 to which the chip selection signal CHS is input in the upper chip 21. Furthermore, as illustrated in FIG. 3, the pads to which the power signals PS are input and the pad to which the distinguishment signal UDS is input in the first upper area 211 of the upper chip 21 may be connected to the pads to which the power signals PS are input in the second lower area 235 of the lower chip 23.

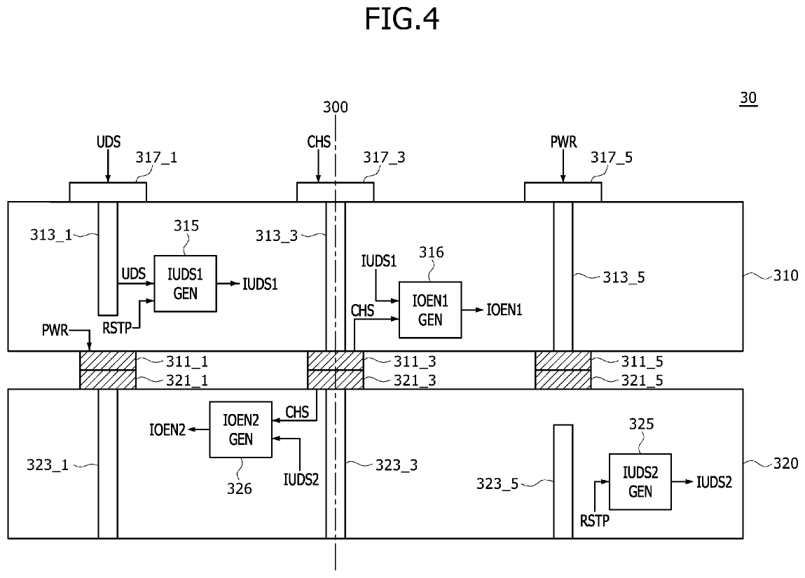

FIG. 4 is a side view of a stacked integrated circuit 30 according to another example of the present disclosure. As illustrated in FIG. 4, the stacked integrated circuit 30 may include an upper chip 310 and a lower chip 320. The upper chip 310 may be rotated around a rotation axis 300, and may be stacked on the lower chip 320 in the form of a mirror symmetric structure.

As illustrated in FIG. 4, the upper chip 310 may include front pads 311_1, 311_3, and 311_5, through vias 313_1, 313_3, and 313_5, a first internal distinguishment signal generation circuit 315 (IUDS1 GEN), a first input/output control signal generation circuit 316 (IOEN1 GEN), and rear pads 317_1, 317_3, and 317_5. The front pads 311_1, 311_3, and 311_5 of the upper chip 310 may be bonded to front pads 3211, 321_3, and 321_5 of the lower chip 320, respectively. Power PWR may be input to the front pad 311_1. The power PWR that is input to the front pad 311_1 may be caused from the power PWR that is input to the rear pad 317_5 and the through via 313_5, but this is merely an embodiment, and the present disclosure is not limited thereto. The through via 3131 may be connected to the rear pad 317_1 to which a distinguishment signal UDS is input. The front pad 311_3 may be connected to the rear pad 317_3 through the through via 313_3. A chip selection signal CHS that is input to the rear pad 3173 may be input to the front pad 311_3 through the through via 313_3. The front pad 311_5 may be connected to the rear pad 3175 through the through via 313_5. The power PWR that is input to the rear pad 317_5 may be input to the front pad 311_5 through the through via 313_5. The first internal distinguishment signal generation circuit 315 may receive the distinguishment signal UDS that is input to the rear pad 317_1 through the through via 313_1, and may generate a first internal distinguishment signal IUDS1 based on the distinguishment signal UDS and a reset signal RSTP. When the reset signal RSTP is generated for an initialization operation, the first internal distinguishment signal generation circuit 315 may initialize the first internal distinguishment signal IUDS1. When the distinguishment signal UDS is received through the rear pad 317_1 and the through via 313_1, the first internal distinguishment signal generation circuit 315 may generate the first internal distinguishment signal IUDS1 by buffering the distinguishment signal UDS. The first input/output control signal generation circuit 316 may be connected to the front pad 311_3, and may receive the chip selection signal CHS that is input to the rear pad 317_3 through the through via 313_3 and the front pad 311_3. The first input/output control signal generation circuit 316 may receive the first internal distinguishment signal IUDS1 from the first internal distinguishment signal generation circuit 315. The first input/output control signal generation circuit 316 may generate a first input/output control signal IOEN1 based on the chip selection signal CHS and the first internal distinguishment signal IUDS1. The first input/output control signal generation circuit 316 may generate the first input/output control signal IOEN1 that is activated for the input/output of a power signal PS in the upper chip 310 by comparing the chip selection signal CHS and the first internal distinguishment signal IUDS1. For example, the first input/output control signal generation circuit 316 may generate the first input/output control signal IOEN1 that is activated when the logic levels of the chip selection signal CHS and the first internal distinguishment signal IUDS1 are set to different logic levels. Furthermore, for example, the first input/output control signal generation circuit 316 may generate the first input/output control signal IOEN1 that is deactivated when the logic levels of the chip selection signal CHS and the first internal distinguishment signal IUDS1 are set to the same logic level.

As illustrated in FIG. 4, the lower chip 320 may include the front pads 321_1, 321_3, and 321_5, through vias 323_1, 323_3, and 323_5, a second internal distinguishment signal generation circuit 325 (IUDS2 GEN), and a second input/output control signal generation circuit 326 (IOEN2 GEN). The front pad 3211 may be connected to the through via 323_1, and may transfer, to the through via 323_1, the power PWR that is input to the front pad 311_1 that has been bonded to the front pad 321_1. The front pad 321_3 may be connected to the through via 323_3, and may receive the chip selection signal CHS through the front pad 311_3 that has been bonded to the front pad 321_3. The second internal distinguishment signal generation circuit 325 may generate a second internal distinguishment signal IUDS2 based on the reset signal RSTP. When the reset signal RSTP is generated for an initialization operation, the second internal distinguishment signal generation circuit 325 may initialize the second internal distinguishment signal IUDS2. The second input/output control signal generation circuit 326 may be connected to the front pad 321_3, and may receive the chip selection signal CHS that is input to the rear pad 317_3 through the through via 313_3, the front pad 311_3, and the front pad 321_3. The second input/output control signal generation circuit 326 may receive the second internal distinguishment signal IUDS2 from the second internal distinguishment signal generation circuit 325. The second input/output control signal generation circuit 326 may generate a second input/output control signal IOEN2 based on the chip selection signal CHS and the second internal distinguishment signal IUDS2. The second input/output control signal generation circuit 326 may generate the second input/output control signal IOEN2 that is activated for the input/output of the power signal PS in the lower chip 320 by comparing the chip selection signal CHS and the second internal distinguishment signal IUDS2. For example, the second input/output control signal generation circuit 326 may generate the second input/output control signal IOEN2 that is activated when the logic levels of the chip selection signal CHS and the second internal distinguishment signal IUDS2 are set to different logic levels. Furthermore, for example, the second input/output control signal generation circuit 326 may generate the second input/output control signal IOEN2 that is deactivated when the logic levels of the chip selection signal CHS and the second internal distinguishment signal IUDS2 are set to same logic level.

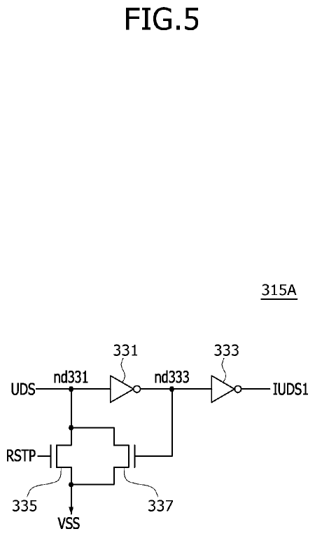

FIG. 5 is a circuit diagram of a first internal distinguishment generation circuit 315A according to an example of the present disclosure. As illustrated in FIG. 5, the first internal distinguishment generation circuit 315A may include inverters 331 and 333 and the NMOS transistors 335 and 337. The inverter 331 may receive a distinguishment signal UDS through a node nd331, and may output the distinguishment signal UDS to a node nd333 by inverting and buffering the distinguishment signal UDS. The NMOS transistor 335 may be turned on when the logic level of a reset signal RSTP is generated as a logic high level, and may drive the node nd331 with a ground voltage VSS. The NMOS transistor 335 may initialize the logic level of the node nd331 to a logic low level when the logic level of the reset signal RSTP is generated as a logic high level. The inverter 333 may generate a first internal distinguishment signal IUDS1 by inverting and buffering a signal of the node nd333. The NMOS transistor 337 may be turned on when the logic level of a signal of the node nd333 is a logic high level, and may drive the node nd333 with the ground voltage VSS. The first internal distinguishment generation circuit 315A may initialize the logic levels of the node nd331 and the first internal distinguishment signal IUDS1 to a logic low level when the logic level of the reset signal RSTP is generated as a logic high level. The first internal distinguishment generation circuit 315A may generate the first internal distinguishment signal IUDS1 by buffering the distinguishment signal UDS.

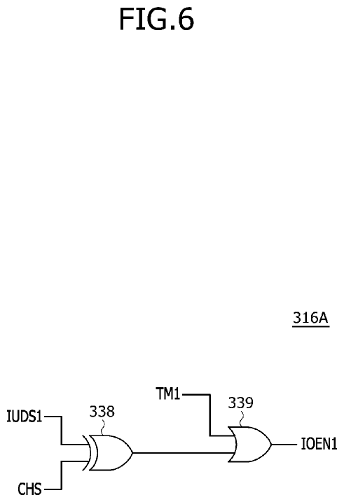

FIG. 6 is a circuit diagram of a first input/output control signal generation circuit 316A according to an example of the present disclosure. As illustrated in FIG. 6, the first input/output control signal generation circuit 316A may include an XOR element 338 and an OR element 339. The XOR element 338 may receive the first internal distinguishment signal IUDS1 and the chip selection signal CHS, and may perform an XOR operation on the first internal distinguishment signal IUDS1 and the chip selection signal CHS. The XOR element 338 may output a signal having a logic high level when the logic levels of the first internal distinguishment signal IUDS1 and the chip selection signal CHS are different logic levels, and may output a signal having a logic low level when the logic levels of the first internal distinguishment signal IUDS1 and the chip selection signal CHS are the same logic level. The OR element 339 may receive an output signal of the XOR element 338 and a first test mode signal TM1, and may perform an OR operation on the output signal and the first test mode signal TM1. The first test mode signal TM1 may be a signal that is applied from the outside of the stacked integrated circuit 30 or that is stored in the stacked integrated circuit for an operation of activating the input and output of the power signal PS in the upper chip 310. The first input/output control signal generation circuit 316A may generate the first input/output control signal IOEN1 in order to activate the input and output of the power signal PS in the upper chip 310 when the logic levels of the first internal distinguishment signal IUDS1 and the chip selection signal CHS are different logic levels or when the first test mode signal TM1 is activated.

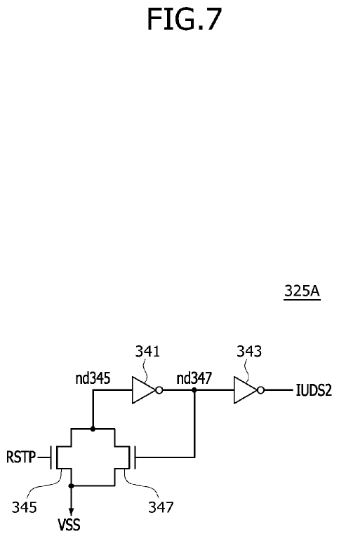

FIG. 7 is a circuit diagram of a second internal distinguishment generation circuit 325A according to an example of the present disclosure. As illustrated in FIG. 7, the second internal distinguishment generation circuit 325A may include inverters 341 and 343 and NMOS transistors 345 and 347. The inverter 341 may output a signal of a node nd345 to a node nd347 by inverting and buffering the signal. The NMOS transistor 345 may be turned on when the logic level of the reset signal RSTP is generated as a logic high level, and may drive the node nd345 with the ground voltage VSS. The NMOS transistor 345 may initialize the logic level of the node nd345 to a logic low level when the logic level of the reset signal RSTP is generated as a logic high level. The inverter 343 may generate the second internal distinguishment signal IUDS2 by inverting and buffering a signal of the node nd347. The NMOS transistor 347 may be turned on when the logic level of the signal of the node nd347 is a logic high level, and may drive the node nd347 with the ground voltage VSS. The second internal distinguishment generation circuit 325A may initialize the logic levels of the node nd345 and the second internal distinguishment signal IUDS2 to a logic low level when the reset signal RSTP is generated as a logic high level. The second internal distinguishment generation circuit 325A may generate the second internal distinguishment signal IUDS2 by buffering the distinguishment signal UDS. The second internal distinguishment generation circuit 325A might not receive the distinguishment signal UDS through the node nd345 unlike the first internal distinguishment generation circuit 315A illustrated in FIG. 5 because the second internal distinguishment generation circuit 325A is included in the lower chip 320, and may generate the second internal distinguishment signal IUDS2 by the reset signal RSTP.

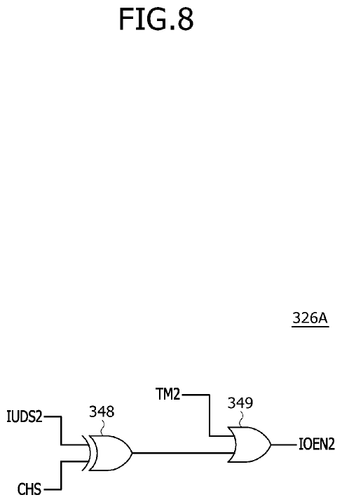

FIG. 8 is a circuit diagram of a second input/output control signal generation circuit 326A according to an example of the present disclosure. As illustrated in FIG. 8, the second input/output control signal generation circuit 326A may include an XOR element 348 and an OR element 349. The XOR element 348 may receive the second internal distinguishment signal IUDS2 and the chip selection signal CHS, and may perform an XOR operation on the second internal distinguishment signal IUDS2 and the chip selection signal CHS. The XOR element 348 may output a logic high level when the logic levels of the second internal distinguishment signal IUDS2 and the chip selection signal CHS are different logic levels, and may output a logic low level when the logic levels of the second internal distinguishment signal IUDS2 and the chip selection signal CHS are the same logic level. The OR element 349 may receive an output signal of the XOR element 338 and a second test mode signal TM2, and may perform an OR operation on the output signal and the second test mode signal TM2. The second test mode signal TM2 may be a signal that is applied from the outside of the stacked integrated circuit 30 or that is stored in the stacked integrated circuit 30 for an operation of activating the input and output of the power signal PS in the lower chip 320. The second input/output control signal generation circuit 326A may generate the second input/output control signal IOEN2 in order to activate the input and output of the power signal PS in the lower chip 320 when the logic levels of the second internal distinguishment signal IUDS2 and the chip selection signal CHS are different logic levels or when the second test mode signal TM2 is activated.

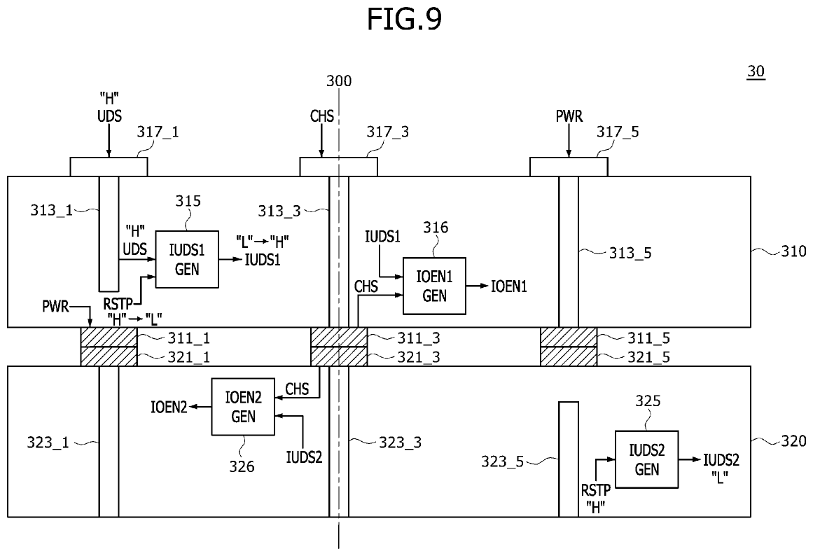

FIGS. 9 to 11 are side views for describing an operation of the stacked integrated circuit 30 according to an example of the present disclosure.

As illustrated in FIG. 9, when the reset signal RSTP having a logic high level “H” is applied for an initialization operation, the first internal distinguishment signal generation circuit 315 may generate the first internal distinguishment signal IUDS1 the logic level of which has been initialized to a logic low level “L,” The second internal distinguishment signal generation circuit 325 may generate the second internal distinguishment signal IUDS2 the logic level of which has been initialized to a logic low level “L.” After the initialization operation is terminated and the logic level of the reset signal RSTP transitions from the logic high level “H” to a logic low level “L”, when the distinguishment signal UDS the logic level of which has been set to a logic high level “H” is received through the rear pad 317_1 and the through via 313_1, the first internal distinguishment signal generation circuit 315 may generate the first internal distinguishment signal IUDS1 the logic level of which is set to a logic high level “H.” The first internal distinguishment signal generation circuit 315 may generate the first internal distinguishment signal IUDS1 the logic level of which has been set to a logic high level “H” in order to indicate the upper chip 310 in response to the distinguishment signal UDS the logic level of which has been set to the logic high level “H.” The second internal distinguishment signal generation circuit 325 may generate the second internal distinguishment signal IUDS2 the logic level of which is set to the logic low level “L” in order to indicate the lower chip 320 in response to the reset signal RSTP having a logic high level “H.”

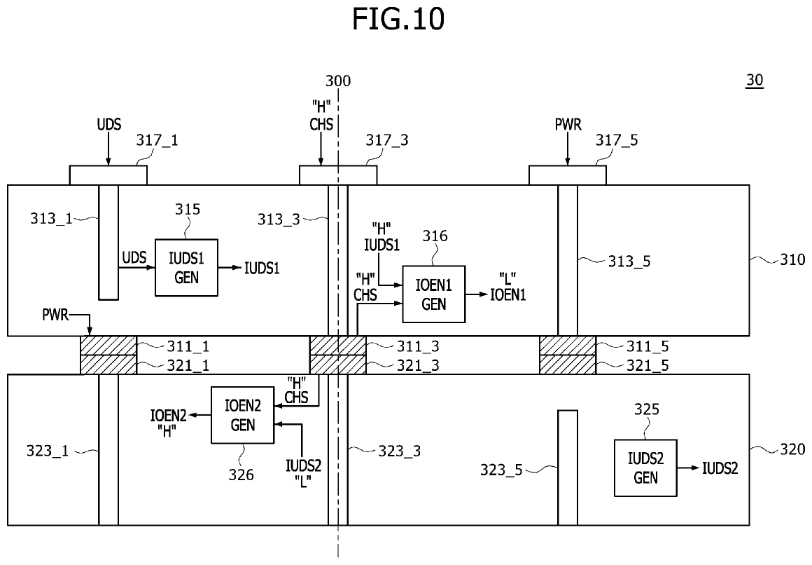

As illustrated in FIG. 10, in the state in which the logic level of the first internal distinguishment signal IUDS1 has been set to a logic high level “H”, when the chip selection signal CHS the logic level of which has been set to a logic high level “H” is received through the rear pad 317_3 and the through via 313_3, the first input/output control signal generation circuit 316 may generate the first input/output control signal IOEN1 the logic level of which has been set to a logic low level “L” in order to deactivate the input and output of the power signal PS in the upper chip 310. Furthermore, in the state in which the logic level of the second internal distinguishment signal IUDS2 has been set to a logic low level “L”, when the chip selection signal CHS the logic level of which has been set to a logic high level “H” is received through the front pads 311_3 and 321_3 and the through via 323_3, the second input/output control signal generation circuit 326 may generate the second input/output control signal IOEN2 the logic level of which has been set to a high level “H” in order to activate the input and output of the power signal PS in the lower chip 320.

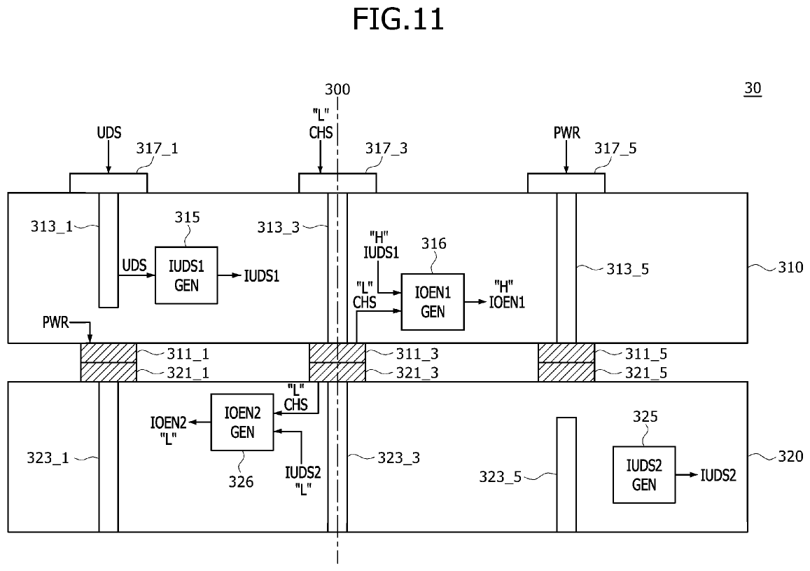

As illustrated in FIG. 11, in the state in which the logic level of which the first internal distinguishment signal IUDS1 has been set to a logic high level “H”, when the chip selection signal CHS the logic level of which has been set to a logic low level “L” is received through the rear pad 317_3 and the through via 313_3, the first input/output control signal generation circuit 316 may generate the first input/output control signal IOEN1 the logic level of which has been set to a logic high level “H” in order to activate the input and output of the power signal PS in the upper chip 310. Furthermore, in the state in which the logic level of the second internal distinguishment signal IUDS2 has been set to a logic low level “L”, when the chip selection signal CHS the logic level of which has been set to a logic low level “L” is received through the front pads 311_3 and 321_3 and the through via 323_3, the second input/output control signal generation circuit 326 may generate the second input/output control signal IOEN2 the logic level of which has been set to a logic low level “L” in order to deactivate the input and output of the power signal PS in the lower chip 320.

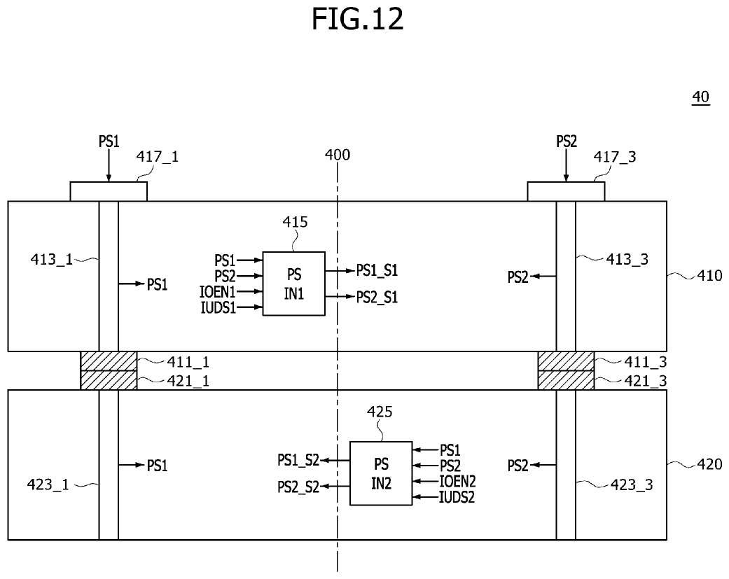

FIG. 12 is a side view of a stacked integrated circuit 40 according to still another example of the present disclosure. As illustrated in FIG. 12, the stacked integrated circuit 40 may include an upper chip 410 and a lower chip 420. The upper chip 410 may be rotated around a rotation axis 400, and may be stacked on the lower chip 420 in the form of a mirror symmetric structure.

As illustrated in FIG. 12, the upper chip 410 may include front pads 411_1 and 411_3, through vias 413_1 and 413_3, a first power signal input circuit 415 (PS IN1), and rear pads 4171 and 417_3. The front pads 411_1 and 411_3 of the upper chip 410 may be bonded to the front pads 421_1 and 421_3 of the lower chip 420, respectively. A first power signal PS1 that is received through the rear pad 4171 may be output through the through via 413_1, and may be applied to the first power signal input circuit 415. A second power signal PS2 that is received through the rear pad 417_3 may be output through the through via 413_3, and may be applied to the first power signal input circuit 415. The first power signal input circuit 415 may generate a first upper power signal PS1_S1 and a second upper power signal PS2_S1 from the first power signal PS1 and the second power signal PS2 based on a first internal distinguishment signal IUDS1 and a first input/output control signal IOEN1. When the input of the first power signal PS1 and the second power signal PS2 is activated in the upper chip 410 in response to the first internal distinguishment signal IUDS1 and the first input/output control signal IOEN1, the first power signal input circuit 415 may generate the second upper power signal PS2_S1 from the first power signal PS1, and may generate the first upper power signal PS1_S1 from the second power signal PS2.

As illustrated in FIG. 12, the lower chip 420 may include the front pads 421_1 and 421_3, through vias 423_1 and 423_3, and a second power signal input circuit 425 (PS IN2). The first power signal PS1 that is received through the rear pad 417_1 may be transferred through the front pads 4111 and 4211, may be output through the through via 423_1, and may be applied to the second power signal input circuit 425. The second power signal PS2 that is received through the rear pad 417_3 may be transferred through the front pads 411_3 and 4213, may be output through the through via 423_3, and may be applied to the second power signal input circuit 425. The second power signal input circuit 425 may generate a first lower power signal PS1_S2 and a second lower power signal PS2_S2 from the first power signal PS1 and the second power signal PS2 based on a second internal distinguishment signal IUDS2 and a second input/output control signal IOEN2. When the input of the first power signal PS1 and the second power signal PS2 is activated in the lower chip 420 in response to the second internal distinguishment signal IUDS2 and the second input/output control signal IOEN2, the second power signal input circuit 425 may generate the first lower power signal PS1_S2 from the first power signal PS1, and may generate the second lower power signal PS2_S2 from the second power signal PS2.

The upper chip 410 may be rotated around the rotation axis 400 and stacked on the lower chip 420 in the form of a mirror symmetric structure. Accordingly, the lower chip 420 may be implemented so that the first lower power signal PS1_S2 is generated from the first power signal PS1 and the second lower power signal PS2_S2 is generated from the second power signal PS2. In contrast, the upper chip 410 may be implemented so that the second upper power signal PS2_S1 is generated from the first power signal PS1 and the first upper power signal PS1_S1 is generated from the second power signal PS2.

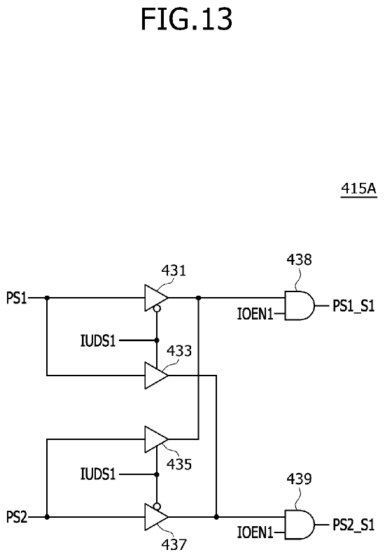

FIG. 13 is a circuit diagram according to an example of a first power signal input circuit 415A according to an example of the present disclosure. As illustrated in FIG. 13, the first power signal input circuit 415A may include drivers 431, 433, 435, and 437 and AND elements 438 and 439. Each of the drivers 431 and 433 may perform a driving operation according to the first power signal PS1 based on the first internal distinguishment signal IUDS1. Each of the drivers 435 and 437 may perform a driving operation according to the second power signal PS2 based on the first internal distinguishment signal IUDS1, Since the logic level of the first internal distinguishment signal IUDS1 is generated as a logic high level in the upper chip 410, only the drivers 433 and 435 among the drivers 431, 433, 435, and 437 may operate. Accordingly, when the input of the first power signal PS1 and the second power signal PS2 is activated in the upper chip 410 and the first input/output control signal IOEN1 the logic level of which has been set to a logic high level is generated, the first upper power signal PS1_S1 that is driven from the second power signal PS2 may be generated through the driver 435 and the AND element 438, and the second upper power signal PS2_S1 that is driven from the first power signal PS1 may be generated through the driver 433 and the AND element 439.

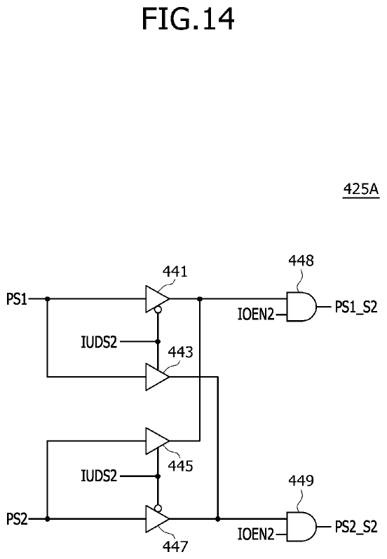

FIG. 14 is a circuit diagram according to an example of a second power signal input circuit 425A according to an example of the present disclosure. As illustrated in FIG. 14, the second power signal input circuit 425A may include drivers 441, 443, 445, and 447 and AND elements 448 and 449. Each of the drivers 441 and 443 may perform a driving operation according to the first power signal PS1 based on the second internal distinguishment signal IUDS2. Each of the drivers 445 and 447 may perform a driving operation according to the second power signal PS2 based on the second internal distinguishment signal IUDS2. Since the logic level of the second internal distinguishment signal IUDS2 is generated as a logic low level in the lower chip 420, only the drivers 441 and 447 among the drivers 441, 443, 445, and 447 may operate. Accordingly, when the input of the first power signal PS1 and the second power signal PS2 is activated in the lower chip 420 and the second input/output control signal IOEN2 the logic level of which has been set to a logic high level is generated, the first lower power signal PS1_S2 that is driven from the first power signal PS1 may be generated through the driver 441 and the AND element 448, and the second lower power signal PS2_S2 that is driven from the second power signal PS2 may be generated through the driver 447 and the AND element 449.

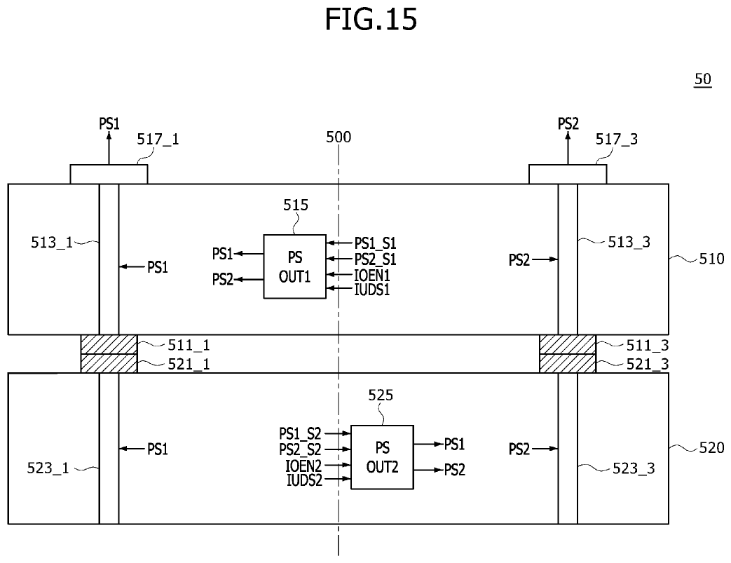

FIG. 15 is a side view of a stacked integrated circuit 50 according to still another example of the present disclosure. As illustrated in FIG. 15, the stacked integrated circuit 50 may include an upper chip 510 and a lower chip 520. The upper chip 510 may be rotated around a rotation axis 500, and may be stacked on the lower chip 520 in the form of a mirror symmetric structure.

As illustrated in FIG. 15, the upper chip 510 may include front pads 511_1 and 511_3, through vias 513_1 and 513_3, a first power signal output circuit 515 (PS OUT1), and rear pads 517_1 and 517_3. The front pads 511_1 and 511_3 of the upper chip 510 may be bonded to front pads 521_1 and 521_3 of the lower chip 520, respectively. A first power signal PS1 that is input from the first power signal output circuit 515 to the through via 513_1 may be output through the rear pad 5171. A second power signal PS2 that is input from the first power signal output circuit 515 to the through via 513_3 may be output through the rear pad 517_3. The first power signal output circuit 515 may generate the first power signal PS1 and the second power signal PS2 from a first upper power signal PS1_S1 and a second upper power signal PS2_S1 based on a first internal distinguishment signal IUDS1 and a first input/output control signal IOEN1. When the output of the first power signal PS1 and the second power signal PS2 is activated in the upper chip 510 in response to the first internal distinguishment signal IUDS1 and the first input/output control signal IOEN1, the first power signal output circuit 515 may generate the first power signal PS1 from the second upper power signal PS2_S1, and may generate the second power signal PS2 from the first upper power signal PS1_S1.

As illustrated in FIG. 15, the lower chip 520 may include the front pads 521_1 and 521_3, through vias 523_1 and 523_3, and a second power signal output circuit 525 (PS OUT2). The first power signal PS1 that is input from the second power signal output circuit 525 to the through via 523_1 may be output through the front pads 521_1 and 5111, the through vias 5131, and the rear pad 5171. The second power signal PS2 that is input from the second power signal output circuit 525 to the through via 523_3 may be output through the front pads 521_3 and 511_3, the through vias 513_3, and the rear pad 517_3. The second power signal output circuit 525 may generate the first power signal PS1 and the second power signal PS2 from the first lower power signal PS1_S2 and the second lower power signal PS2_S2 based on the second internal distinguishment signal IUDS2 and the second input/output control signal IOEN2. When the output of the first power signal PS1 and the second power signal PS2 is activated in the lower chip 520 in response to the second internal distinguishment signal IUDS2 and the second input/output control signal IOEN2, the second power signal output circuit 525 may generate the first power signal PS1 from the first lower power signal PS1_S2, and may generate the second power signal PS2 from the second lower power signal PS2_S2.

The upper chip 510 may be rotated around the rotation axis 500 and stacked on the lower chip 520 in the form of a mirror symmetric structure. Accordingly, the lower chip 520 may be implemented so that the first power signal PS1 is generated from the first lower power signal PS1_S2 and the second power signal PS2 is generated from the second lower power signal PS2_S2. In contrast, the upper chip 510 may be implemented so that the first power signal PS1 is generated from the second upper power signal PS2_S1 and the second power signal PS2 is generated from the first upper power signal PS1_S1.

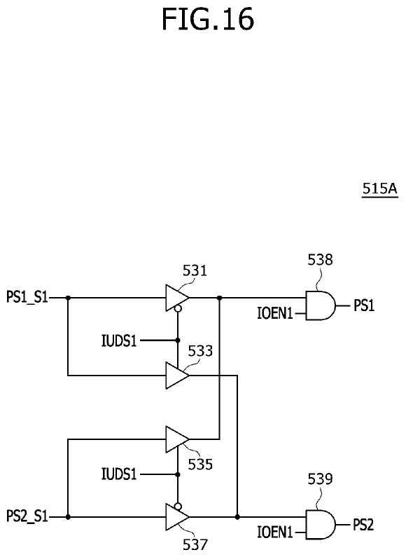

FIG. 16 is a circuit diagram according to an example of a first power signal output circuit 515A according to an example of the present disclosure. As illustrated in FIG. 16, the first power signal output circuit 515A may include drivers 531, 533, 535, and 537 and AND elements 538 and 539. Each of the drivers 531 and 533 may perform a driving operation according to the first upper power signal PS1_S1 based on the first internal distinguishment signal IUDS1. Each of the drivers 535 and 537 may perform a driving operation according to the second upper power signal PS2_S1 based on the first internal distinguishment signal IUDS1. Since the logic level of the first internal distinguishment signal IUDS1 is generated as a logic high level in the upper chip 510, only the drivers 533 and 535 among the drivers 531, 533, 535, and 537 may operate. Accordingly, when the output of the first power signal PS1 and the second power signal PS2 is activated in the upper chip 510 and the first input/output control signal IOEN1 the logic level of which has been set to a logic high level is generated, the first power signal PS1 that is driven from the second upper power signal PS2_S1 may be generated through the driver 535 and the AND element 538, and the second power signal PS2 that is driven from the first upper power signal PS1_S1 may be generated through the driver 533 and the AND element 539.

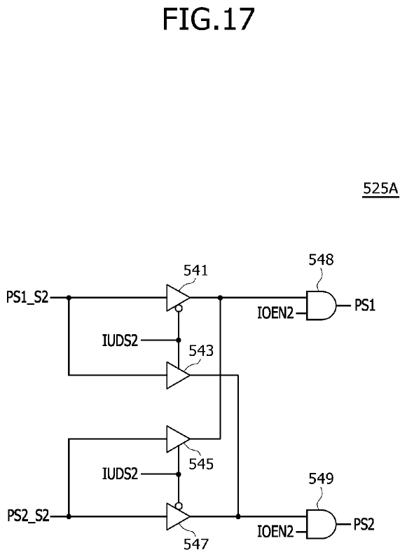

FIG. 17 is a circuit according to an example of a second power signal output circuit 525A that is included in the stacked integrated circuit illustrated in FIG. 15. As illustrated in FIG. 17, the second power signal output circuit 525A may include drivers 541, 543, 545, and 547 and AND elements 548 and 549. Each of the drivers 541 and 543 may perform a driving operation according to the first power signal PS1 based on the second internal distinguishment signal IUDS2. Each of the drivers 545 and 547 may perform a driving operation according to the second power signal PS2 based on the second internal distinguishment signal IUDS2. Since the logic level of the second internal distinguishment signal IUDS2 is generated as a logic low level in the lower chip 520, only the drivers 541 and 547 among the drivers 541, 543, 545, and 547 may operate. Accordingly, when the output of the first power signal PS1 and the second power signal PS2 is activated in the lower chip 520 and the second input/output control signal IOEN2 the logic level of which has been set to a logic high level is generated, the first power signal PS1 that is driven from the first lower power signal PS1_S2 may be generated through the driver 541 and the AND element 548, and the second power signal PS2 that is driven from the second lower power signal PS2_S2 may be generated through the driver 547 and the AND element 549.

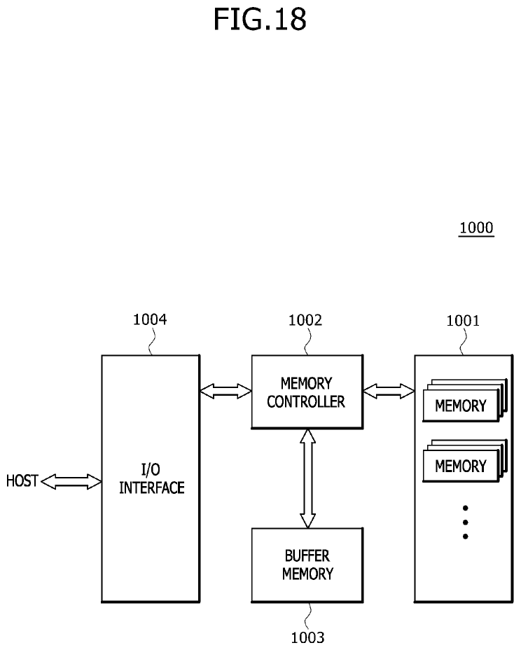

The stacked integrated circuit 20 described with reference to FIG. 2, the stacked integrated circuit 30 described with reference to FIG. 4, the stacked integrated circuit 40 described with reference to FIG. 12, and the stacked integrated circuit 50 described with reference to FIG. 15 may be applied to an electronic system which includes a memory system, a graphic system, a computing system, a mobile system, etc. For example, referring to FIG. 18, an electronic system 1000 according to an embodiment of the present disclosure may include a data storage unit 1001, a memory controller 1002, buffer memory 1003, and an input/output (I/O) interface 1004.

The data storage unit 1001 may store data (not illustrated) that is applied from the memory controller 1002 in response to a control signal from the memory controller 1002, may read data (not illustrated) that is stored in the data storage unit 1001, and may output the read data to the memory controller 1002. The data storage unit 1001 may include a nonvolatile memory capable of continuously storing data without losing the data although power is blocked. The nonvolatile memory may be implemented as flash memory (e.g., a NOR flash memory or a NAND flash memory), phase change random access memory (PRAM), resistive random access memory (RRAM), spin transfer torque random access memory (STTRAM), or magnetic random access memory (MRAM).

The memory controller 1002 may decode an instruction that is applied from an external device (or a host device) through the input/output interface 1004, and may control the input/output of data to/from the data storage unit 1001 and the buffer memory 1003 based on a result of the decoding. In FIG. 18, the memory controller 1002 has been illustrated as being one block, but a controller for controlling the data storage unit 1001 and a controller for controlling the buffer memory 1003, that is, volatile memory, may be independently constructed in the memory controller 1002.

The buffer memory 1003 may store data to be processed in the memory controller 1002, that is, data (not illustrated) that is input to and output from the data storage unit 1001. The buffer memory 1003 may store data (not illustrated) that is applied from the memory controller 1002 in response to a control signal. The buffer memory 1003 may include the stacked integrated circuit 20 described with reference to FIG. 2, the stacked integrated circuit 30 described with reference to FIG. 4, the stacked integrated circuit 40 described with reference to FIG. 12, and the stacked integrated circuit 50 described with reference to FIG. 15. The buffer memory 1003 may read data that is stored in the buffer memory 1003, and may output the read data to the memory controller 1002. The buffer memory 1003 may include volatile memory, such as dynamic random access memory (DRAM), mobile DRAM, or static random access memory (SRAM).

The input/output interface 1004 may provide a physical connection between the memory controller 1002 and an external device (or a host) so that the memory controller 1002 may receive a control signal for a data input/output from the external device and may exchange data with the external device. The input/output interface 1004 may include one of various interface protocols, such as a USB, an MMC, PCI-E, SAS, SATA, PATA, an SCSI, an ESDI, and an IDE.

The electronic system 1000 may be used as an auxiliary memory device or external storage device of a host device. The electronic system 1000 may include a solid state disk (SSD), universal serial bus memory (USB), secure digital (SD) card, a mini secure digital (mSD) card, a micro SD card, a secure digital high capacity (SDHC) card, a memory stick card, a smart media (SM) card, a multi-media card (MMC), an embedded MMC (eMMC), a compact flash (CF) card, etc.

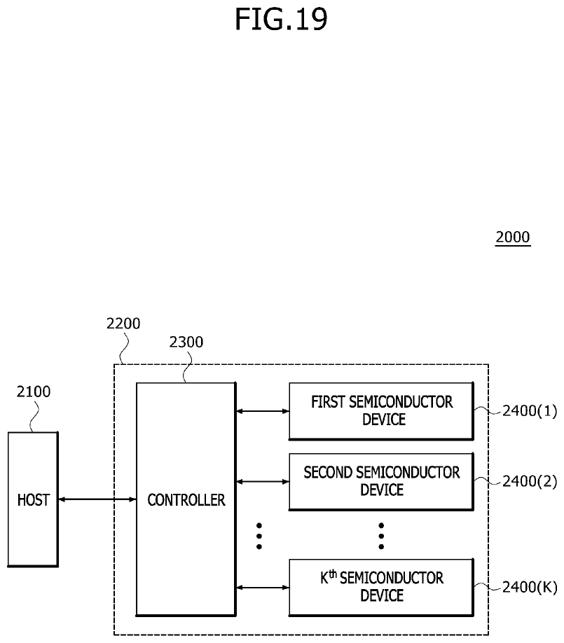

FIG. 19 is a block diagram illustrating a construction according to an embodiment of an electronic system 2000 according to another embodiment of the present disclosure. As illustrated in FIG. 19, the electronic system 2000 may include a host 2100 and a semiconductor system 2200.

The host 2100 and the semiconductor system 2200 may mutually transmit signals by using an interface protocol. The interface protocol that is used between the host 2100 and the semiconductor system 2200 may include a multi-media card (MMC), an enhanced small disk interface (ESDI), integrated drive electronics (IDE), peripheral component interconnect—express (PCI-E), advanced technology attachment (ATA), serial ATA (SATA), parallel ATA (PATA), a serial attached SCSI (SAS), a universal serial bus (USB), etc.

Each of the semiconductor devices 2400(K:1) may include the stacked integrated circuit 20 described with reference to FIG. 2, the stacked integrated circuit 30 described with reference to FIG. 4, the stacked integrated circuit 40 described with reference to FIG. 12, and the stacked integrated circuit 50 described with reference to FIG. 15. Each of the semiconductor devices 2400(K:1) may be implemented as one of dynamic random access memory (DRAM), phase change random access memory (PRAM), resistive random access memory (RRAM), magnetic random access memory (MRAM), and ferroelectric random access memory (FRAM).

The embodiments may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A stacked integrated circuit comprising:
an upper chip that is rotated around a rotation axis and stacked on a lower chip in a mirror symmetric structure form,
wherein the lower chip and the upper chip are stacked in a front and front connection structure form,
the upper chip configured to generate a first internal distinguishment signal based on a distinguishment signal,
the upper chip configured to generate a first input and output (input/output) control signal for an input/output of a power signal based on the first internal distinguishment signal and a chip selection signal,
the lower chip configured to generate a second internal distinguishment signal based on a reset signal, and
the lower chip configured to generate a second input/output control signal for the input/output of the power signal based on the second internal distinguishment signal and the chip selection signal.

2. The stacked integrated circuit of claim 1, wherein the upper chip comprises:
a first rear pad configured to receive the distinguishment signal; and
a second rear pad configured to receive the chip selection signal.

3. The stacked integrated circuit of claim 2, wherein the upper chip comprises a first internal distinguishment signal generation circuit configured to receive the distinguishment signal through a first through via that is connected to the first rear pad and configured to generate the first internal distinguishment signal.

4. The stacked integrated circuit of claim 3, wherein the first internal distinguishment signal generation circuit is configured to initialize the first internal distinguishment signal based on the reset signal and then generate the first internal distinguishment signal based on the distinguishment signal.

5. The stacked integrated circuit of claim 3, wherein the upper chip further comprises a first input/output control signal generation circuit configured to generate the first input/output control signal by receiving the chip selection signal through a second through via and a first front pad that are connected to the second rear pad and configured to receive the first internal distinguishment signal from the first internal distinguishment signal generation circuit.

6. The stacked integrated circuit of claim 5, wherein the first input/output control signal generation circuit is configured to generate the first input/output control signal by comparing logic levels of the chip selection signal and the first internal distinguishment signal.

7. The stacked integrated circuit of claim 5, wherein the lower chip comprises a second front pad that is bonded to the first front pad, and comprises a second input/output control signal generation circuit configured to generate the second input/output control signal by receiving the chip selection signal through the first front pad and the second front pad and receiving the second internal distinguishment signal.

8. The stacked integrated circuit of claim 7,
wherein the lower chip further comprises a second internal distinguishment signal generation circuit configured to generate the second internal distinguishment signal, and
wherein the second internal distinguishment signal is initialized based on the reset signal.

9. The stacked integrated circuit of claim 2, wherein the upper chip further comprises a third rear pad configured to receive power.

10. The stacked integrated circuit of claim 9, wherein:
the upper chip comprises a first front pad configured to receive the power, and
the lower chip comprises:
a second front pad that is bonded to the first front pad; and
a through via that is connected to the second front pad, the second front pad configured to receive the power.

11. A stacked integrated circuit comprising:
an upper chip that is rotated around a rotation axis and stacked on a lower chip in a mirror symmetric structure form,
wherein the lower chip and the upper chip are stacked in a front and front connection structure form, and
each of the lower chip and the upper chip is configured to control an input of a first power signal and a second power signal based on an internal distinguishment signal and an input and output (input/output) control signal.

12. The stacked integrated circuit of claim 11, wherein:
the internal distinguishment signal comprises a first internal distinguishment signal that is generated from the upper chip and a second internal distinguishment signal that is generated from the lower chip, and
logic levels of the first internal distinguishment signal and the second internal distinguishment signal are generated to have different logic levels each other.

13. The stacked integrated circuit of claim 12, wherein:
the input/output control signal comprises a first input/output control signal that is generated from the upper chip and a second input/output control signal that is generated from the lower chip, and
the first input/output control signal and the second input/output control signal are selectively activated in response to a chip selection signal.

14. The stacked integrated circuit of claim 13, wherein the upper chip comprises a first power signal input circuit configured to generate a first upper power signal and a second upper power signal from the first power signal and the second power signal based on the first internal distinguishment signal and the first input/output control signal.

15. The stacked integrated circuit of claim 14, wherein the first power signal input circuit is configured to generate the second upper power signal from the first power signal and generate the first upper power signal from the second power signal.

16. The stacked integrated circuit of claim 14, wherein the lower chip comprises a second power signal input circuit configured to generate a first lower power signal and a second lower power signal from the first power signal and the second power signal based on the second internal distinguishment signal and the second input/output control signal.

17. The stacked integrated circuit of claim 16, wherein the second power signal input circuit is configured to generate the first lower power signal from the first power signal and generate the second lower power signal from the second power signal.

18. A stacked integrated circuit comprising:
an upper chip that is rotated around a rotation axis and stacked on a lower chip in a mirror symmetric structure form,
wherein the lower chip and the upper chip are stacked in a front and front connection structure form, and
each of the lower chip and the upper chip is configured to control an output of a first power signal and a second power signal based on an internal distinguishment signal and an input and output (input/output) control signal.

19. The stacked integrated circuit of claim 18, wherein:
the internal distinguishment signal comprises a first internal distinguishment signal that is generated from the upper chip and a second internal distinguishment signal that is generated from the lower chip, and
logic levels of the first internal distinguishment signal and the second internal distinguishment signal are generated to have different logic levels each other.

20. The stacked integrated circuit of claim 19, wherein:
the input/output control signal comprises a first input/output control signal that is generated from the upper chip and a second input/output control signal that is generated from the lower chip, and
the first input/output control signal and the second input/output control signal are selectively activated in response to a chip selection signal.

21. The stacked integrated circuit of claim 20, wherein the upper chip comprises a first power signal output circuit configured to generate the first power signal and the second power signal from a first upper power signal and a second upper power signal based on the first internal distinguishment signal and the first input/output control signal.

22. The stacked integrated circuit of claim 21, wherein the first power signal output circuit is configured to generate the first power signal from the second upper power signal and generate the second power signal from the first upper power signal.

23. The stacked integrated circuit of claim 21, wherein the lower chip comprises a second power signal output circuit configured to generate the first power signal and the second power signal from a first lower power signal and a second lower power signal based on the second internal distinguishment signal and the second input/output control signal.

24. The stacked integrated circuit of claim 23, wherein the second power signal input circuit is configured to generate the first power signal from the first lower power signal and generate the second power signal from the second lower power signal.
